(19) United States
(12) Patent Application Publication
(10) Pub. No.: US 2026/0276312 A1
(43) Pub. Date: Sep. 17, 2026

(54) BENDABLE SHAPEABLE HEAT PLATE STRUCTURE

(71) Applicant: NIDEC CHAUN-CHOUNG TECHNOLOGY CORPORATION, NEW TAIPEI CITY (TW)

(72) Inventors: Ming-Yang JIANG, NEW TAIPEI CITY (TW); Jia-Lin WU, NEW TAIPEI CITY (TW)

(21) Appl. No.: 19/530,380

(22) Filed: Feb. 5, 2026

(30) Foreign Application Priority Data
Mar. 11, 2025 (TW) 114108915

(51) Int. Cl. F28D 15/02; F28D 15/04

(52) U.S. Cl. CPC F28D 15/0241; F28D 15/046

(57) ABSTRACT

A bendable shapeable heat plate structure includes an inner bending plate, an outer bending plate, and a capillary structure. The inner bending plate has an inner concave portion with a surrounding inner sealing edge and includes first and second inner plate sections connected by an inner bending section. The outer bending plate is stacked with the inner bending plate and has an outer concave portion facing the inner concave portion and an outer sealing edge at its periphery, along with first and second outer plate sections connected by an outer bending section. The capillary structure is attached to the inner concave portion. At least one strip-shaped support structure is integrally formed on the outer concave portion, extends within the outer bending section toward the first and second outer plate sections, and abuts an inner surface of the inner bending section.

### BACKGROUND OF THE DISCLOSURE

### Technical Field

The present disclosure relates to a heat conduction and dissipation component, and more particularly to a bendable shapeable heat plate structure.

### Description of Related Art

Related-art heat plates are mainly formed by stacking two plate bodies together. Because the interior is kept under vacuum, support structures must be included between the two plate bodies to withstand pressure, thereby maintaining the internal chamber for the enclosed working fluid to undergo phase change.

However, when a heat plate is formed into a curved shape, the support structures located within the bent portion often fail to effectively about the bent regions between the two plate bodies due to the geometry of the bend. As a result, the plate bodies may collapse or cave in at the bent portion, adversely affecting the formation of the internal chamber. This significantly degrades the thermal performance of the heat plate.

In view of the above, the inventor has undertaken extensive research and applied theoretical principles to address these deficiencies, and ultimately developed the present disclosure, which is rationally designed and effectively improves the foregoing issues.

### SUMMARY OF THE DISCLOSURE

It is an objective of the present disclosure to provide a bendable shapeable heat plate structure. By using a strip-shaped support structure that is integrally formed with one of the plate bodies, the required support structure is formed at the bent portion of the heat plate, thereby avoiding or reducing thermal performance degradation caused by depression issues.

To achieve the above objective, the present disclosure provides a bendable shapeable heat plate structure, including an inner bending plate, an outer bending plate, and a capillary structure. The inner bending plate is provided with an inner concave portion thereon, and an inner sealing edge is disposed at a periphery of the inner concave portion. The inner bending plate includes a first inner plate section, a second inner plate section, and an inner bending section connected between the first inner plate section and the second inner plate section. The outer bending plate is stacked with the inner bending plate and is provided with an outer concave portion that faces the inner bending plate. An outer sealing edge is disposed at a periphery of the outer concave portion. The outer bending plate includes a first outer plate section, a second outer plate section, and an outer bending section connected between the first outer plate section and the second outer plate section. The capillary structure is attached to the inner concave portion of the inner bending plate. At least one strip-shaped support structure is integrally formed on the outer concave portion of the outer bending plate. The strip-shaped support structure is located within the outer bending section, extends toward the first and second outer plate sections, and abuts against the inner surface of the inner bending section of the inner bending plate.

### BRIEF DESCRIPTION OF THE DRAWINGS

FIG. 1 is an exploded perspective view of the present disclosure.

FIG. 2 is an exploded perspective view of the present disclosure from another angle.

FIG. 3 is a schematic perspective assembled view of the present disclosure.

FIG. 4 is a cross-sectional view taken along line 4-4 of FIG. 3.

FIG. 4A is a partial enlarged view of FIG. 4.

FIG. 5 is a cross-sectional view taken along line 5-5 of FIG. 4.

### DETAILED DESCRIPTION

To allow the examiner to further understand the features and technical content of the present disclosure, please refer to the following detailed description and the accompanying drawings of the present disclosure. The accompanying drawings are provided for reference and illustration only and are not intended to limit the present disclosure.

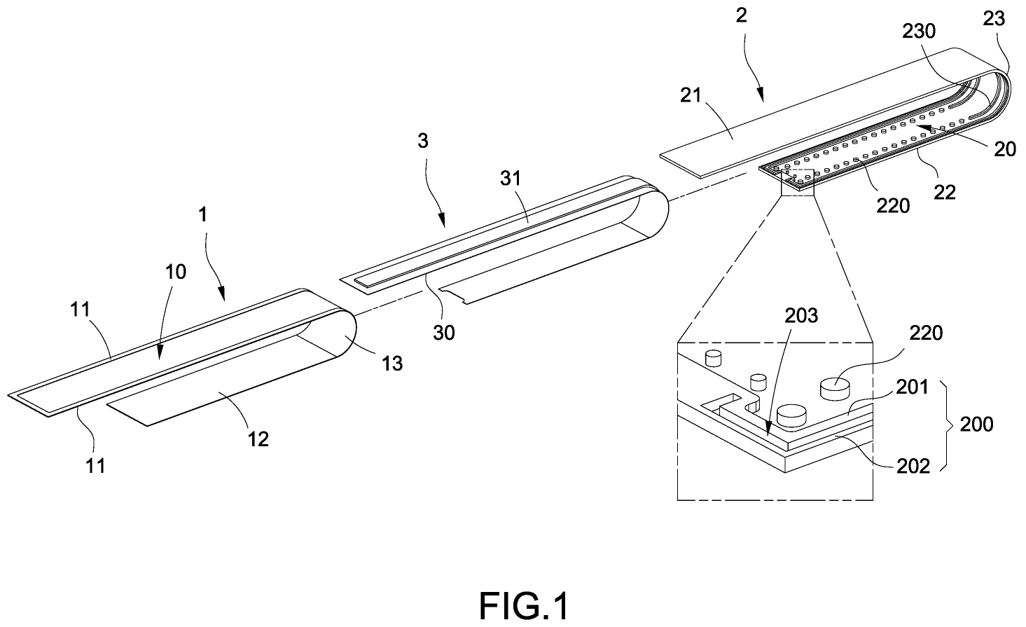

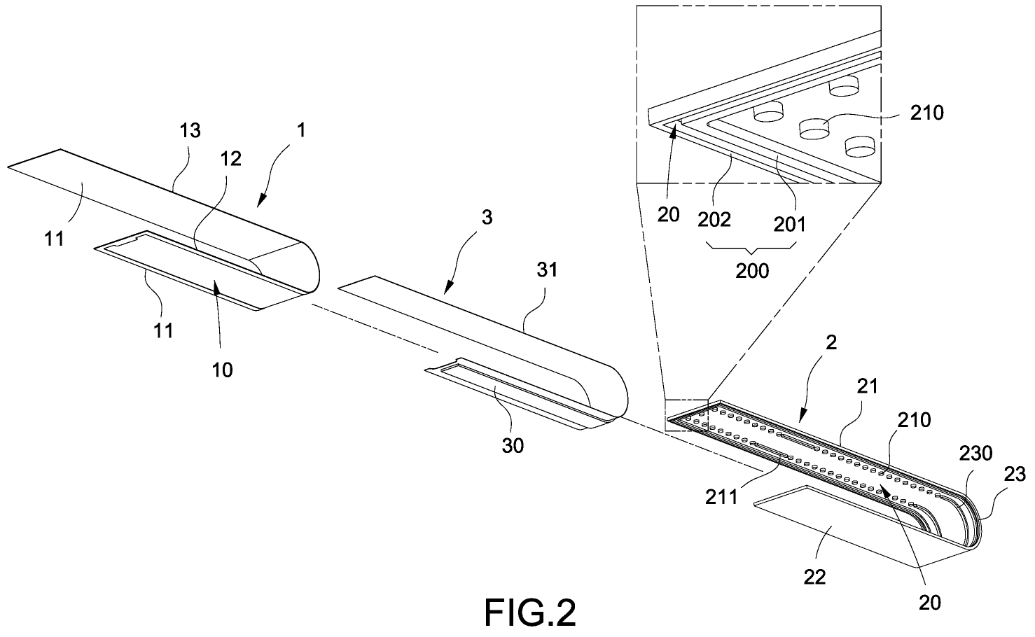

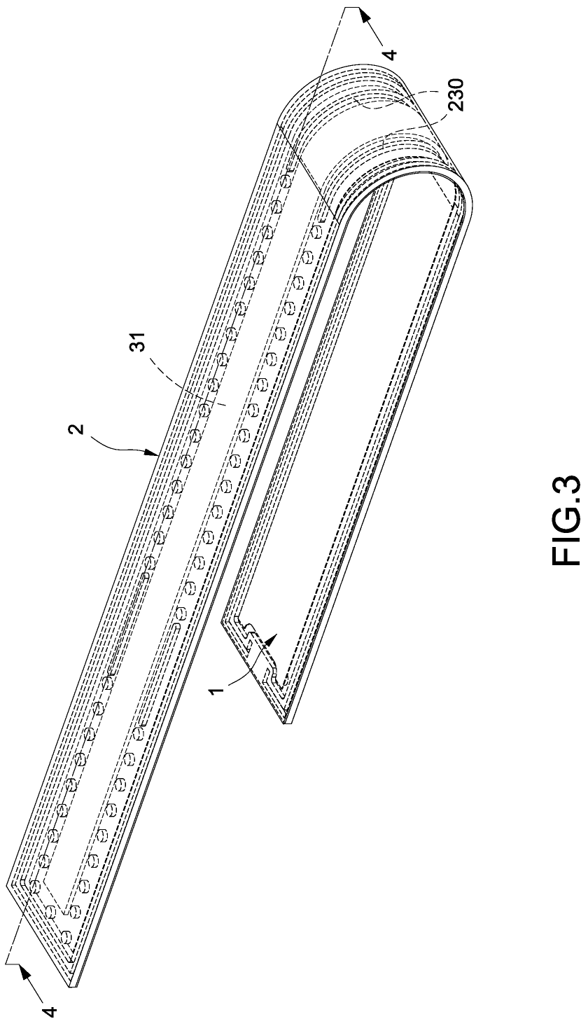

Please refer to FIG. 1, FIG. 2, and FIG. 3, which respectively shows an exploded perspective view, an exploded perspective view from another angle, and a schematic assembled perspective view of the present disclosure. The present disclosure provides a bendable shapeable heat plate structure which includes an inner bending plate 1, an outer bending plate 2, and a capillary structure 3. The structure is described as follows:

The inner bending plate 1 may be made of a material with good thermal conductivity, such as copper or aluminum. The inner bending plate 1 forms the inner side portion of the heat plate body after bending. An inner concave portion 10 is recessed on the curved outer surface of the inner bending plate 1, and an inner sealing edge 100 is disposed at the periphery of the inner concave portion 10. In addition, after being bent, the inner bending plate 1 includes a first inner plate section 11, a second inner plate section 12, and an inner bending section 13 connected between the first inner plate section 11 and the second inner plate section 12.

The outer bending plate 2 may also be made of a material with good thermal conductivity, such as copper or aluminum. The outer bending plate 2 forms the outer side portion of the heat plate body after bending. An outer concave portion 20 is recessed on the curved inner surface of the outer bending plate 2, and an outer sealing edge 200 is disposed at the periphery of the outer concave portion 20. In the embodiment of the present disclosure, the outer sealing edge 200 includes an inner edge portion 201, an outer edge portion 202, and a solder groove 203 formed between the inner edge portion 201 and the outer edge portion 202. Solder is filled in the solder groove 203 to hermetically seal together the inner sealing edge 100 and the outer sealing edge 200. In addition, after being bent, the outer bending plate 2 includes a first outer plate section 21, a second outer plate section 22, and an outer bending section 23 connected between the first outer plate section 21 and the second outer plate section 22.

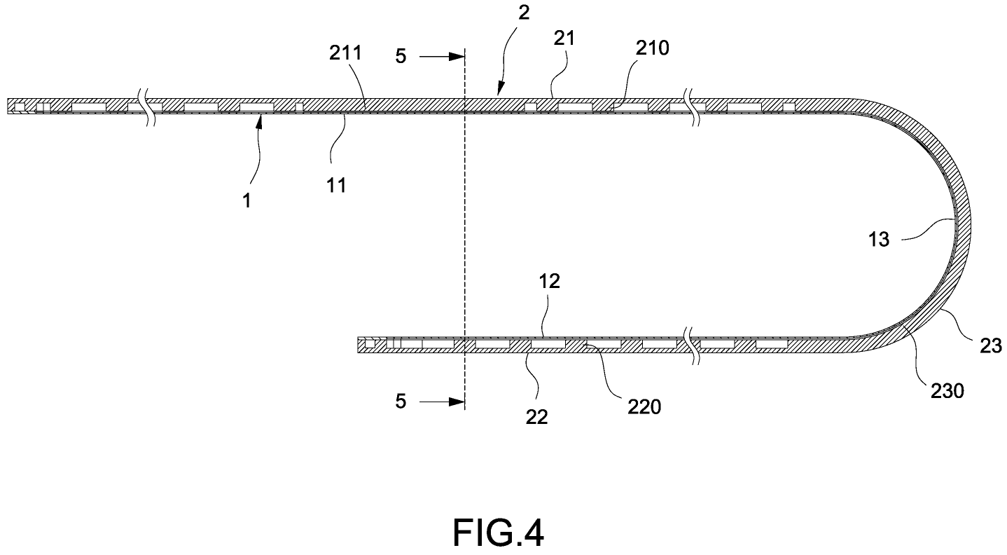

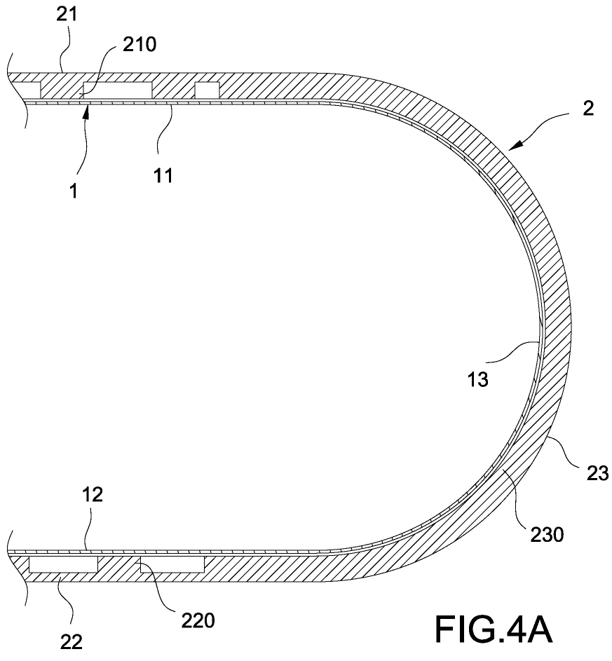

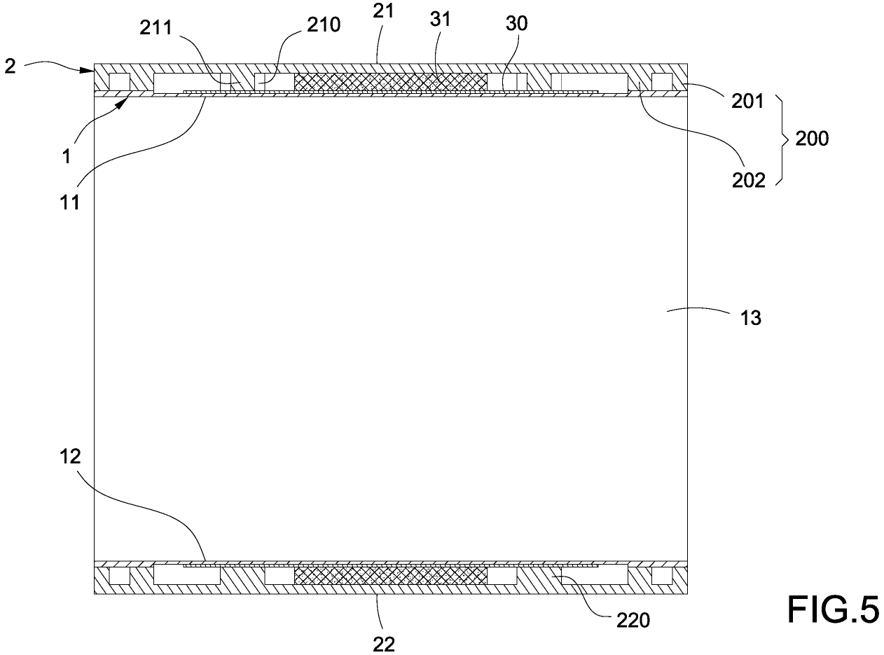

As shown in FIG. 4 and FIG. 4A, the inner bending plate 1 and the outer bending plate 2 are stacked together according to their inner and outer relationship, and the inner sealing edge 100 and the outer sealing edge 200 are stacked and hermetically sealed together as described above. Also referring to FIG. 1, FIG. 2, and FIG. 5, the capillary structure 3 is attached to the inner concave portion 10 of the inner bending plate 1. In the embodiment of the present disclosure, the capillary structure 3 may include a layered capillary 30 and a strip-shaped capillary 31. The layered capillary 30 extends from the first inner plate section 11 of the inner bending plate 1, through the inner bending section 13, and into the second inner plate section 12; in an example embodiment, the layered capillary 30 fully covers the inner concave portion 10. The strip-shaped capillary 31 is stacked on the layered capillary 30 and extends at least through the inner bending section 13 into the first inner plate section 11 and the second inner plate section 12.

Referring again to FIG. 1 and FIG. 2, the present disclosure is primarily characterized in that at least one strip-shaped support structure 230, as well as a plurality of first support pillars 210 and a plurality of second support pillars 220, is integrally formed on the outer concave portion 20 of the outer bending plate 2. The strip-shaped support structure 230 is located within the outer bending section 23 and extends toward the first outer plate section 21 and the second outer plate section 22. The first support pillars 210 are distributed within the first outer plate section 21 and may be arranged in one or more rows at intervals along the strip-shaped support structure 230 toward one end of the first outer plate section 21. The second support pillars 220 are distributed within the second outer plate section 22 and may likewise be arranged in one or more rows at intervals along the strip-shaped support structure 230 toward one end of the second outer plate section 22. Specifically, the cross-sections of the first support pillars 210 and the second support pillars 220 may have various geometric shapes, such as cylindrical or elongated columnar shapes.

Thus, through the structural configuration described above, the bendable shapeable heat plate structure of the present disclosure is obtained.

Accordingly, as shown in FIG. 4 and FIG. 4A, the strip-shaped support structure 230 is integrally formed on the outer concave portion 20 of the outer bending plate 2. This provides the necessary mutual supporting strength for the bending configuration between the inner bending section 13 and the outer bending section 23. The outer bending section 23 abuts against the inner surface of the inner bending section 13 to avoid or reduce depressions caused by bending at this location, thereby effectively preventing any resulting attenuation or loss of thermal performance of the heat plate. Furthermore, the first support pillars 210 provide support strength between the first inner plate section 11 and the first outer plate section 21, and the second support pillars 220 provide support strength between the second inner plate section 12 and the second outer plate section 22. These pillars may likewise be formed integrally on the outer concave portion 20 of the outer bending plate 2. With respect to the integral forming manner, etching techniques may be employed to etch the outer concave portion 20 on the outer bending plate 2 while leaving the strip-shaped support structure 230, the first support pillars 210, and the second support pillars 220 reserved. Alternatively, stamping techniques may be used to stamp the outer concave portion 20 on the outer bending plate 2 while causing the strip-shaped support structure 230, the first support pillars 210, and the second support pillars 220 to protrude and form within the outer concave portion 20.

In summary, the present disclosure indeed achieves the purposes described in the specification and overcome the deficiencies of the related art. Furthermore, because the present disclosure possesses novelty and inventiveness, it fully meets the requirements for a patent application. Accordingly, the present disclosure is submitted under the Patent Law, and it is respectfully requested that a detailed examination be conducted and that a patent be granted to protect the rights of the inventor.

However, the above description relates only to some feasible embodiments of the present disclosure and is not intended to limit the scope of the present disclosure. Therefore, all equivalent technical modifications, means, or variations based on the contents of the specification and the drawings of the present disclosure are likewise included within the scope of the present disclosure.

What is claimed is:

1. A bendable shapeable heat plate structure, comprising:
an inner bending plate comprising an inner concave portion recessed on the inner bending plate, and an inner sealing edge disposed at a periphery of the inner concave portion, wherein the inner bending plate comprises a first inner plate section, a second inner plate section, and an inner bending section connected between the first inner plate section and the second inner plate section;
an outer bending plate stacked on the inner bending plate and comprising an outer concave portion recessed on the outer bending plate and facing the inner bending plate, wherein the outer bending plate further comprises an outer sealing edge disposed at a periphery of the outer concave portion, and a first outer plate section, a second outer plate section, and an outer bending section connected between the first outer plate section and the second outer plate section; and
a capillary structure attached to the inner concave portion of the inner bending plate;
wherein at least one strip-shaped support structure is disposed on the outer concave portion of the outer bending plate and is integrally formed with the outer bending plate, the strip-shaped support structure is located within the outer bending section and extends toward the first outer plate section and the second outer plate section respectively, and abuts against an inner surface of the inner bending section of the inner bending plate.

2. The bendable shapeable heat plate structure according to claim 1, wherein the inner bending plate is made of copper or aluminum.

3. The bendable shapeable heat plate structure according to claim 2, wherein the outer bending plate is made of copper or aluminum.

4. The bendable shapeable heat plate structure according to claim 1, wherein the outer bending plate is made of copper or aluminum.

5. The bendable shapeable heat plate structure according to claim 1, wherein the outer sealing edge comprises an inner edge portion, an outer edge portion, and a solder groove defined between the inner edge portion and the outer edge portion, and solder is filled in the solder groove to hermetically seal together the inner sealing edge and the outer sealing edge.

6. The bendable shapeable heat plate structure according to claim 1, wherein on the outer concave portion of the outer bending plate, a plurality of first support pillars are disposed within the first outer plate section, and a plurality of second support pillars are disposed within the second outer plate section.

7. The bendable shapeable heat plate structure according to claim 6, wherein the first support pillars are arranged in one or more rows at intervals extending along the strip-shaped support structure toward one end of the first outer plate section, and the second support pillars are arranged in one or more rows at intervals extending along the strip-shaped support structure toward one end of the second outer plate section.

8. The bendable shapeable heat plate structure according to claim 7, wherein the first support pillars and the second support pillars disposed on the outer concave portion are all integrally formed with the outer bending plate.

9. The bendable shapeable heat plate structure according to claim 6, wherein the first support pillars and the second support pillars disposed on the outer concave portion are all integrally formed with the outer bending plate.

10. The bendable shapeable heat plate structure according to claim 1, wherein the capillary structure comprises a layered capillary.

11. The bendable shapeable heat plate structure according to claim 10, wherein the layered capillary extends from within the first inner plate section of the inner bending plate through the inner bending section into the second inner plate section to fully cover the inner concave portion.

12. The bendable shapeable heat plate structure according to claim 11, wherein the capillary structure further comprises a strip-shaped capillary, and the strip-shaped capillary is stacked on the layered capillary and extends at least through the inner bending section into the first inner plate section and the second inner plate section.

13. The bendable shapeable heat plate structure according to claim 10, wherein the capillary structure further comprises a strip-shaped capillary, and the strip-shaped capillary is stacked on the layered capillary and extends at least through the inner bending section into the first inner plate section and the second inner plate section.
